(19) United States
(12) Patent Application Publication
(10) Pub. No.: US 2024/0290590 A1
(43) Pub. Date: Aug. 29, 2024

(54) PLASMA MONITORING SYSTEM

(71) Applicant: Samsung Display Co., LTD., Yongin-si (KR)

(72) Inventors: YOUNGGIL PARK, Yongin-si (KR); JAE-HO EO, Yongin-si (KR)

(21) Appl. No.: 18/520,360

(22) Filed: Nov. 27, 2023

(30) Foreign Application Priority Data
Feb. 24, 2023 (KR) 10-2023-0024679

(51) Int. Cl. H01J 37/32; H01J 37/02; H01J 37/22

(52) U.S. Cl. CPC H01J 37/32972; H01J 37/023; H01J 37/226

(57) ABSTRACT

A plasma monitoring system includes a gate valve disposed on a first side of a chamber, where the gate valve is opened or closed in conjunction with a plasma monitoring operation, a viewport structure disposed outside the chamber and including a plurality of light transmitting parts, and an optical emission spectroscopy disposed outside the chamber, where the optical emission spectroscopy monitors plasma by receiving plasma light transmitted through at least one of the plurality of light transmitting parts of the viewport structure.

This application claims priority to Korean Patent Application No. 10-2023-0024679, filed on Feb. 24, 2023, and all the benefits accruing therefrom under 35 U.S.C. § 119, the content of which in its entirety is herein incorporated by reference.

### BACKGROUND

### 1. Field

Embodiments relate to a plasma monitoring system that monitors plasma generated in a sputtering process.

### 2. Description of the Related Art

As information technology develops, the importance of a display device as a connection medium between a user and information is being highlighted. For example, various types of display device such as a liquid crystal display device (LCD), an organic light emitting display device (OLED), a plasma display device (PDP), a quantum dot display device or the like are widely used in various fields.

The display device may include a plurality of thin films formed on a substrate. Methods for forming the thin film may include a chemical vapor deposition (CVD), a physical vapor deposition (PVD), or the like. Among such methods, the PVD may include a sputtering process, a thermal evaporation process, an E-beam evaporation process, or the like.

### SUMMARY

A sputtering process has a desired feature of easily obtaining the thin film regardless of a material of the substrate, and is widely used in the manufacturing process of the display device. However, as the display device becomes larger in size, more sophistication of the method of forming the thin film is desired. In particular, a uniformity of the thin film is an important factor that determines a quality or performance of the display device, and various attempts are being made to improve the uniformity of the thin film.

Embodiments provide a plasma monitoring system.

A plasma monitoring system according to embodiments of the disclosure may include a gate valve, a viewport structure, and an optical emission spectroscopy. In such embodiments, the gate valve is disposed on a first side of a chamber and opened or closed in conjunction with a plasma monitoring operation. In such embodiments, the viewport structure is disposed outside the chamber and includes a plurality of light transmitting parts. In such embodiments, the optical emission spectroscopy is disposed outside the chamber and monitors plasma by receiving plasma light transmitted through at least one of the plurality of light transmitting parts of the viewport structure.

In an embodiment, the gate valve may be opened only during the plasma monitoring operation.

In an embodiment, the viewport structure may further include a driving device connected to the viewport structure, and the driving device rotates or linearly moves the viewport structure.

In an embodiment, the viewport structure may further include a cold trap part spaced apart from the plurality of light transmitting parts, and the cold trap part aggregates and collects plasma particles.

In an embodiment, the plasma monitoring system may further include a shutter disposed between the viewport structure and the chamber.

In an embodiment, a third opening may be defined in the shutter, and the third opening may overlap at least one of the plurality of light transmitting parts.

In an embodiment, the plasma monitoring system may further include an optical lens disposed between the viewport structure and the optical emission spectroscopy.

In an embodiment, the optical lens may be a convex lens.

In an embodiment, the plurality of light transmitting parts may be arranged in a circular array form in the viewport structure.

In an embodiment, the plurality of light transmitting parts may be arranged in an nxm matrix form in the viewport structure, where n is a natural number of 1 or greater, and m is the natural number of 2 or greater.

A plasma monitoring system according to embodiments of the disclosure may include a gate valve, a viewport structure, a shutter, and an optical emission spectroscopy. In such embodiments, the gate valve is disposed on a first side of a chamber and opened or closed in conjunction with a plasma monitoring operation. In such embodiments, the viewport structure is disposed outside the chamber and includes a plurality of light transmitting parts. In such embodiments, the shutter is disposed between the viewport structure and the chamber, and the shutter rotates or linearly moves. In such embodiments, the optical emission spectroscopy is disposed outside the chamber and monitors plasma by receiving plasma light transmitted through at least one of the plurality of light transmitting parts of the viewport structure.

In an embodiment, the gate valve may be opened only during the plasma monitoring operation.

In an embodiment, the viewport structure may further include a cold trap part spaced apart from plurality of light transmitting parts, and the cold trap part may aggregate and collect plasma particles.

In an embodiment, a third opening may be defined in the shutter, and the third opening may overlap at least one of the plurality of light transmitting parts.

In an embodiment, the shutter may be provided in plurality to overlap the plurality of light transmitting parts, respectively.

In an embodiment, the shutter may further include a driving device which rotates or linearly moves the viewport structure.

In an embodiment, the plasma monitoring system may further include an optical lens disposed between the viewport structure and the optical emission spectroscopy.

In an embodiment, the optical lens may be a convex lens.

In an embodiment, the plurality of light transmitting parts may be arranged in a circular array form in the viewport structure.

In an embodiment, the plurality of light transmitting parts may be arranged in an nxm matrix form in the viewport structure, where n is a natural number of 1 or greater, and m is the natural number of 2 or greater.

According to embodiments of the disclosure, a plasma monitoring system may include a gate valve disposed on a first side of a chamber and configured to be opened or closed in conjunction with a plasma monitoring operation, a viewport structure, and an optical emission spectroscopy. The gate valve may be open only in a plasma monitoring state, and in a closed state shields the viewport structure from plasma particles, thereby preventing the plasma particles from being deposited on the viewport structure. Accordingly, the plasma monitoring system may continue to monitor the plasma while a sputtering process in progress.

In such embodiments, the plasma monitoring system may further include the viewport structure disposed outside the chamber and including a plurality of light transmitting parts. At least one (one light transmitting part) among the plurality of light transmitting parts may be used for monitoring the plasma. In the plasma monitoring process, when the plasma particles are deposited on the one light-transmitting part, light transmittance of the one light transmitting part may decrease. In this case, the plasma monitoring system may continue to monitor the plasma by replacing the one light transmitting part with another light transmitting part.

In such embodiments, the plasma monitoring system may further include the shutter disposed between the chamber and the viewport structure. The shutter may shield other light transmitting parts other than at least the one light transmitting part used for the plasma monitoring among the plurality of light transmitting parts. The shutter may prevent the plasma particles from being deposited on remaining light transmitting parts. Accordingly, the plasma monitoring system may continue to monitor the plasma while the sputtering process in progress.

In such embodiments, the plasma monitoring system may further include an optical lens disposed between the viewport structure and the optical emission spectroscopy. The optical lens may be a convex lens. Accordingly, the plasma monitoring system may measure a plasma source located at a certain distance or more.

### BRIEF DESCRIPTION OF THE DRAWINGS

FIG. 1 is a block view illustrating a plasma monitoring system according to an embodiment of the disclosure.

FIG. 2 is a cross-sectional view illustrating an embodiment of a process processor included in the plasma monitoring system of FIG. 1.

FIGS. 3 and 4 are perspective views of an embodiment of a gate valve included in the processor of FIG. 2.

FIGS. 5 to 16 are view illustrating an embodiment of a data collector included in the plasma monitoring system of FIG. 1.

FIG. 17 is a cross-sectional view illustrating a display device that is an example of an object that may be formed using the plasma monitoring system of FIG. 1.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in more detail with reference to the accompanying drawings. The same reference numerals and/or reference characters are used for the same components in the drawings, and any repetitive detailed descriptions of the same components will be omitted or simplified.

FIG. 1 is a block view illustrating a plasma monitoring system according to an embodiment of the disclosure.

Referring to FIG. 1, a plasma monitoring system 1 according to an embodiment of the disclosure may include a process processor 10, a data collector 20, and a controller 30.

The process processor 10 may perform (or control an operation for) a sputtering process. Plasma may be generated during the sputtering process. In the sputtering process, plasma conditions may affect film quality.

The data collector 20 and the controller 30 may monitor a plasma state and control the sputtering process in real-time.

The data collector 20 may receive plasma data SI from the process processor 10. The plasma data SI may be collected in real-time while the sputtering process is in progress.

The data collector 20 may perform emission spectroscopic analysis based on the plasma data S1. Accordingly, the data collector 20 may monitor uniformity of the plasma, an abnormal state of the plasma, or the like. In an embodiment, for example, the data collector 20 may monitor physical properties of an object to be processed (e.g., composition of an oxide thin film, moisture, uniformity of a raw material, or the like) and a process state in real-time while the sputtering process is in progress.

However, the disclosure is not limited thereto. In an embodiment, the data collector 20 may further include various components for monitoring the sputtering process. In an embodiment, for example, the data collector 20 may further include a temperature sensor or the like.

The controller 30 may receive emission spectrometry analysis data S2 of data collector 20. The emission spectrometry analysis data S2 may be collected in real-time while the sputtering process is in progress.

The controller 30 may control the sputtering process in real-time based on the emission spectrometry analysis data S2. The controller 30 may provide a control signal S3 to the process processor 10. In an embodiment, for example, the control signal S3 may control process factors (temperature, power supply voltage, or the like) of the process processor 10. The control signal S3 may be provided in real-time while the sputtering process is in progress.

However, the disclosure is not limited thereto. In an embodiment, the controller 30 may further include various components for controlling the sputtering process. In an embodiment, for example, the controller 30 may further include a machine learning system. The machine learning system may include one or more data collection circuits and analysis systems.

The data collection circuit may collect various data including the emission spectroscopy analysis data S2. In such an embodiment, as described above, the data may be collected in real-time while the sputtering process is in progress.

The analysis system may include one or more processors having associated memory. In an embodiment, for example, the processor may include an application specific integrated circuit (ASIC), a central processing unit (CPU) for general or special purpose, a digital signal processor (DSP), a graphics processing unit (GPU), a field programmable gate array (FPGA), or the like. The analysis system may include a training module and an analysis module.

The training module may create and train a plurality of machine learning models for classifying the physical properties of the object to be processed according to the process factor. Generation and training of the plurality of machine learning models may be based on a training data set provided by the data collection circuit. In an embodiment, for example, the training module may collect the training data set from the data collection circuit and train the analysis module for analyzing the physical properties of the object to be processed using the training data set.

The analysis module may be a joint fusion model in which two or more neural networks independently trained using data collected from different types of data collection circuits are integrated. Alternatively, the analysis module may be a deep neural network trained using a single data source collected from the data collection circuit. In an embodiment, for example, the analysis module may generate a process recipe to which an optimal process factor is applied when desired physical properties of the object to be processed are input. The controller 30 may provide the control signal S3 to the process processor 10 to apply the process recipe. Accordingly, the sputtering process may be automatically controlled in real-time.

In an embodiment, when light transmittance of one light transmitting part 214 among a plurality of light transmitting parts 214 and 214′ in a viewport structure 210 to be described later decreases, the controller 30 may provide a spare (for example, another light transmitting part 214′). Accordingly, the plasma monitoring system may continue to monitor the plasma while a sputtering process in progress despite the decrease in light transmittance.

In an embodiment, for example, the data collector 20 and the controller 30 may be implemented as different devices as shown in FIG. 1. However, the disclosure is not limited thereto. In an alternative embodiment, the data collector 20 and the controller 30 may be implemented as a same device.

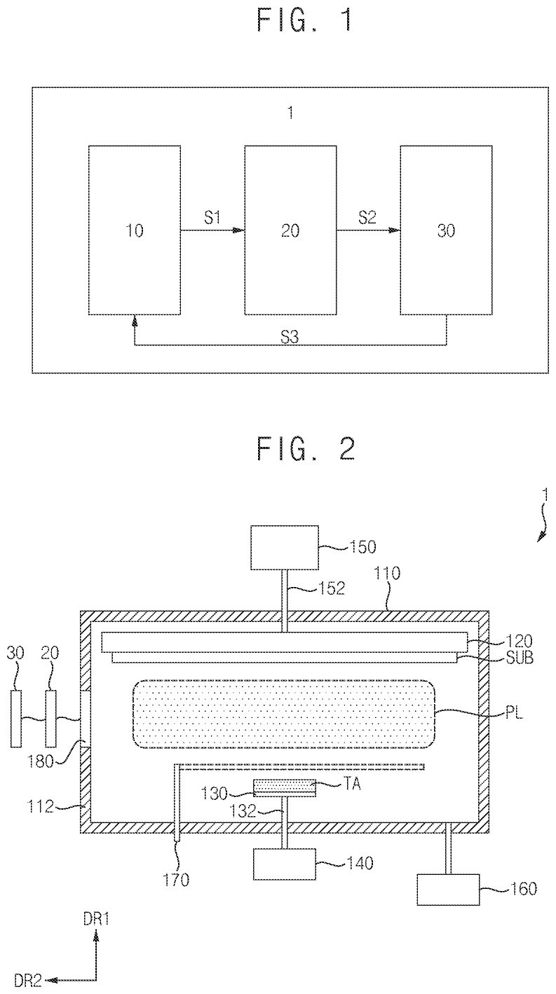

FIG. 2 is a cross-sectional view illustrating an embodiment of the process processor included in the plasma monitoring system of FIG. 1.

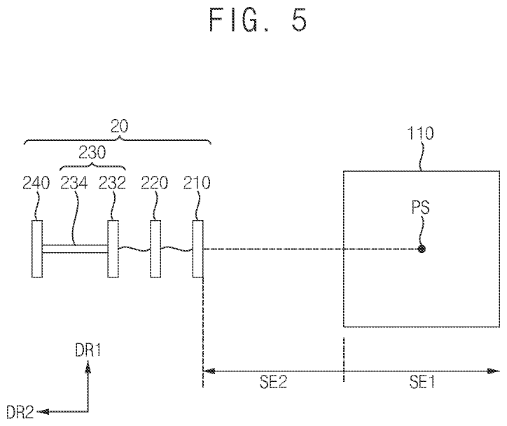

Referring to FIGS. 1 and 2, an embodiment of the plasma monitoring system 1 may include the process processor 10, the data collector 20, and the controller 30. The data collector 20 and the controller 30 may be disposed outside the process processor 10. Detailed features of the components of the data collector 20 will be described later with reference to FIG. 5.

In an embodiment, the process processor 10 may include a chamber 110, a first support part 120, a second support part 130, a power source 140, a gas supply part 150, an exhaust part 160, a shield part 170, and a gate valve 180.

The chamber 110 may define an internal space (e.g., an internal region SE1 of the chamber 110 of FIG. 5) in which the sputtering process is performed. In an embodiment, for example, the chamber 110 may have a rectangular shape. In such an embodiment, the chamber 110 may include a top surface, a bottom surface, and a plurality of side surfaces. Each of the top and bottom surfaces may face each other in a first direction DR1. The plurality of side surfaces may cross each of the top and bottom surfaces.

However, the disclosure is not limited thereto. In an embodiment, the chamber 110 may have various shapes. In an embodiment, for example, the chamber 110 may have a circular shape, an elliptical shape, a polygonal shape other than the rectangular shape, or the like.

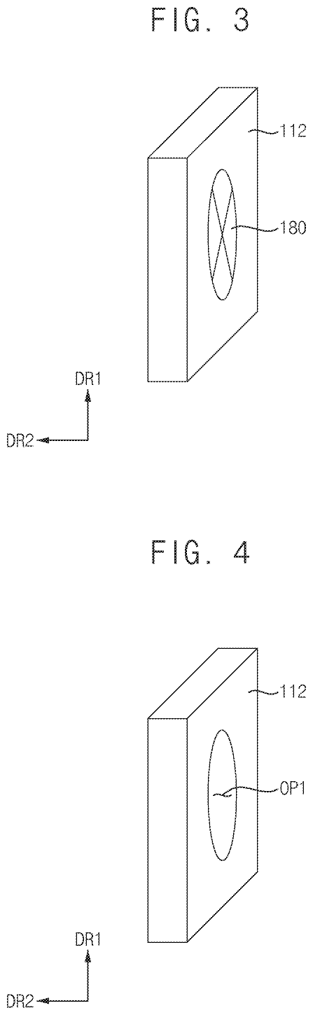

In an embodiment, the gate valve 180 may be disposed on a first side 112 of the chamber 110. Detailed features of the gate valve 180 will be described later with reference to FIGS. 3 and 4.

Each of the first support part 120 and the second support part 130 may be disposed within the chamber 110. Each of the first support part 120 and the second support part 130 may face each other in the first direction DR1.

In an embodiment, for example, the first support part 120 may be an electrostatic chuck, and the second support part 130 may be a moving stage including a driving motor. However, the disclosure is not limited thereto. In an embodiment, for example, the process processor 10 may include various components capable of fixing a substrate SUB and a target TA while the sputtering process is performed in various ways.

In an embodiment, for example, the substrate SUB may be seated on the first support part 120 and the target TA may be seated on the second support part 130. In other words, the substrate SUB may be disposed adjacent to the top surface of the chamber CH, and the target TA may be disposed adjacent to the bottom surface of the chamber CH. However, the disclosure is not limited thereto. In an alternative embodiment, for example, the substrate SUB may be disposed adjacent to the bottom surface of the chamber CH, and the target TA may be disposed adjacent to the top surface of the chamber CH. In such an embodiment where hen the substrate SUB is disposed adjacent to the bottom surface of the chamber CH, the first support part 120 may be omitted.

The substrate SUB may correspond to the object to be processed described in FIG. 1. In an embodiment, the substrate SUB may be a display substrate. In an embodiment, for example, the substrate SUB may be a substrate for a display device such as an organic light-emitting display device, a liquid crystal display device, a plasma display device, or the like. The substrate SUB may be a bare substrate or a substrate on which a structure such as a thin film or line is formed.

The target TA may include a material (i.e., target material) to be deposited on the substrate SUB. In an embodiment, for example, the sputtering process may be a process of forming an oxide semiconductor thin film.

In an embodiment, the target TA may include a metal oxide. In an embodiment, for example, the target TA may include zinc oxide (ZnOₓ), gallium oxide (GaOₓ), tin oxide (SnOₓ), titanium oxide (TiOₓ), indium oxide (InOₓ), indium-gallium oxide (IGO), indium-zinc oxide (IZO), gallium-zinc oxide (GZO), zinc-tin oxide (ZTO), zinc-magnesium Oxide (ZMO), zinc-zirconium Oxide (ZnZrₓO_{y}), indium-zinc-tin oxide (IZTO), indium-gallium-zinc oxide (IGZO), indium-gallium-hafnium oxide (IGHO), tin-aluminum-zinc oxide (TAZO), indium-gallium-tin oxide (IGTO), indium-tin-gallium-zinc oxide (ITGZO), or the like. These may be used alone or in combination with each other.

In an alternative embodiment, the target TA may include a metal or an alloy thereof. In an embodiment, for example, the target TA may include titanium (Ti), chromium (Cr), tantalum (Ta), zirconium (Zr), magnesium (Mg), hafnium (Hf), magnesium (Mg), aluminum (Al), nickel. (Ni), gallium (Ga), manganese (Mn), copper (Cu), silver (Ag), zinc (Zn), tin (Sn), indium (In), or the like. These may be used alone or in combination with each other.

However, the disclosure is not limited thereto. Each of the substrate SUB and the target TA may include various materials. In an embodiment, for example, the substrate SUB may be a semiconductor wafer, and the target TA may include various metals or metal oxides.

An electric field may be formed or generated in the inner space of the chamber CH. In an embodiment, for example, an anode electrode may be disposed adjacent to the substrate SUB, and a cathode electrode may be disposed adjacent to the target TA. Accordingly, the electric field may be formed between the target TA and the substrate SUB.

The power source 140 may be connected to the target TA. The power source 140 may apply a voltage to the target TA.

The gas supply part 150 may supply gas to the inner space of the chamber CH through a gas inlet pipe 152.

In an embodiment, the gas may be an inert gas. In an embodiment, for example, the gas may include argon (Ar). However, the disclosure is not limited thereto.

In an alternative embodiment, , the gas may be a reactive gas. In an embodiment, for example, the gas may include oxygen (02). A reaction product between the oxygen gas and the target material may be deposited on the substrate SUB.

In an embodiment, for example, the sputtering process may include following processes. First, the voltage of the power source 140 may be applied to the target TA. The gas (e.g., the reactive gas) may be provided to the inner space of the chamber CH. Plasma PL may be generated in the inner space of the chamber CH. Specifically, the gas may be separated into positive ions and electrons. The positive ions may collide with the target TA connected to the cathode electrode along the electric field. Accordingly, the target material may be released from the target TA and deposited on the substrate SUB.

The exhaust part 160 may be connected to a gas discharge pipe for exhausting a residual gas in the inner space of the chamber CH. Accordingly, the residual gas may be effectively discharged from the inner space.

The shield part 170 may be disposed between the substrate SUB and the target TA. In an embodiment, for example, the shutter SH may serve as a dummy between processes. In a case, a first deposition layer including a first material and a second deposition layer including a second material may be sequentially formed on the substrate SUB. In this case, after forming the first deposition layer and before forming the second deposition layer, a remaining amount of the first material may be deposited on the shutter SH. Accordingly, the first material may be effectively prevented from being included in the second deposition layer.

FIGS. 3 and 4 are perspective views of an embodiment of a gate valve included in the processor of FIG. 2.

Particularly, FIG. 3 shows a state in which the gate valve 180 is closed, and FIG. 4 shows a state in which the gate valve 180 is opened.

Referring to FIGS. 2, 3, and 4, in an embodiment, the gate valve 180 may be disposed on the first side 112 of the chamber 110.

In an embodiment, the gate valve 180 may be opened/closed in conjunction with a plasma monitoring operation. In an embodiment, the gate valve 180 may be opened only while monitoring the plasma.

In an embodiment, for example, the gate valve 180 may shield the data collector 20 from the plasma particles in the closed state. On the other hand, the gate valve 180 may define a first opening OP1 through which the inner space of the chamber 110 and an outer space of the chamber 110 (e.g., an outer region SE2 of the chamber 110 of FIG. 5) communicate with each other. Accordingly, in the state in which the gate valve 180 is opened, the data collector 20 may collect data PL about the plasma within the process processor 10.

The process processor 10 described above with reference to FIGS. 1 to 4 is exemplary. In an embodiment, for example, the process processor 10 may further include various components or the disclosed components may be changed to other components.

In an embodiment, for example, the process processor 10 may further include a magnetron or the like. The magnetron may include electromagnets having different polarities. In an embodiment, for example, the magnetron may form a magnetic field from a N pole to a S pole of the electromagnet. Electrons located in the magnetic field may move along the magnetic field and collide with the reaction gas in a molecular state. Accordingly, ionization of the reaction gas may be promoted. In addition, the sputtering process described above is also exemplary and may be variously changed.

In a plasma monitoring system according to a comparative embodiment, the data collector 20 may be connected to a wall of the chamber 110. The data collector 20 may include an optical emission spectroscopy (e.g., an optical emission spectroscopy 240 of FIG. 5). As the sputtering process progresses, the target material may be randomly deposited on the wall of the chamber 110. Accordingly, a thickness at which the target material is deposited on the wall of the chamber 110 may increase. As the thickness increases, the light transmittance may decrease. Accordingly, in the plasma monitoring system according to the comparative embodiment may be difficult to monitor the plasma PL as the sputtering process progresses.

In an alternative embodiment, components for maintaining a vacuum may be further included between the process processor 10 and the data collector 20. In an embodiment, for example, data collector 20 may be disposed within a tube extending from process processor 10. The tube may include stainless-steel or the like.

Hereinafter, an embodiment of the data collector 20 will be described in detail with reference to FIGS. 5 to 16. The data collector 20 included in the plasma monitoring system 1 according to embodiments of the disclosure may continuously monitor the plasma PL while the sputtering process is in progress.

FIGS. 5 to 16 are view illustrating an embodiment of a data collector included in the plasma monitoring system of FIG. 1.

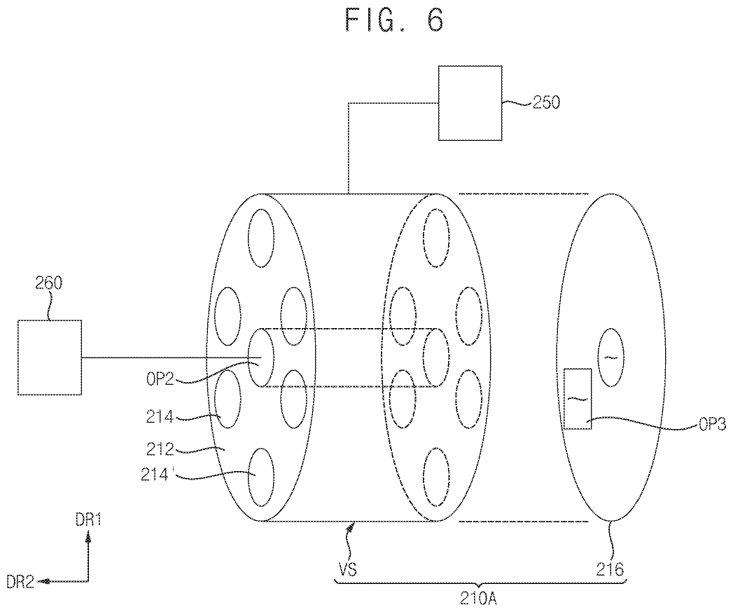

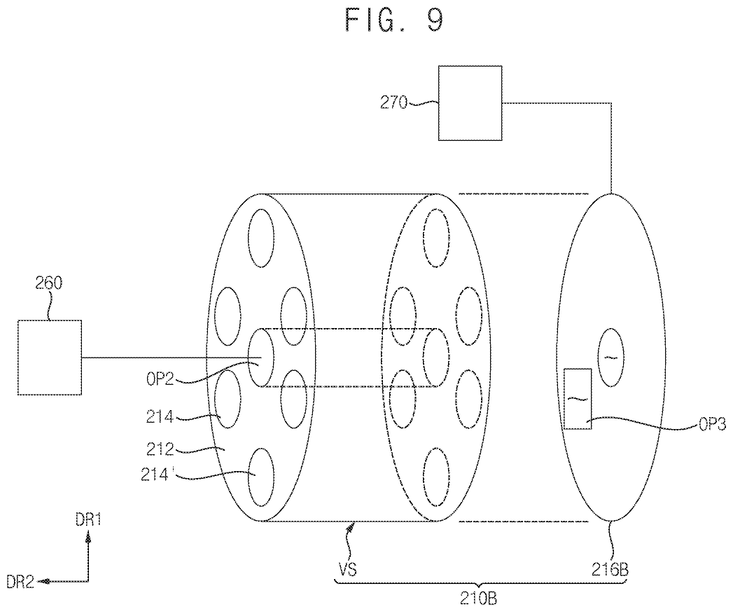

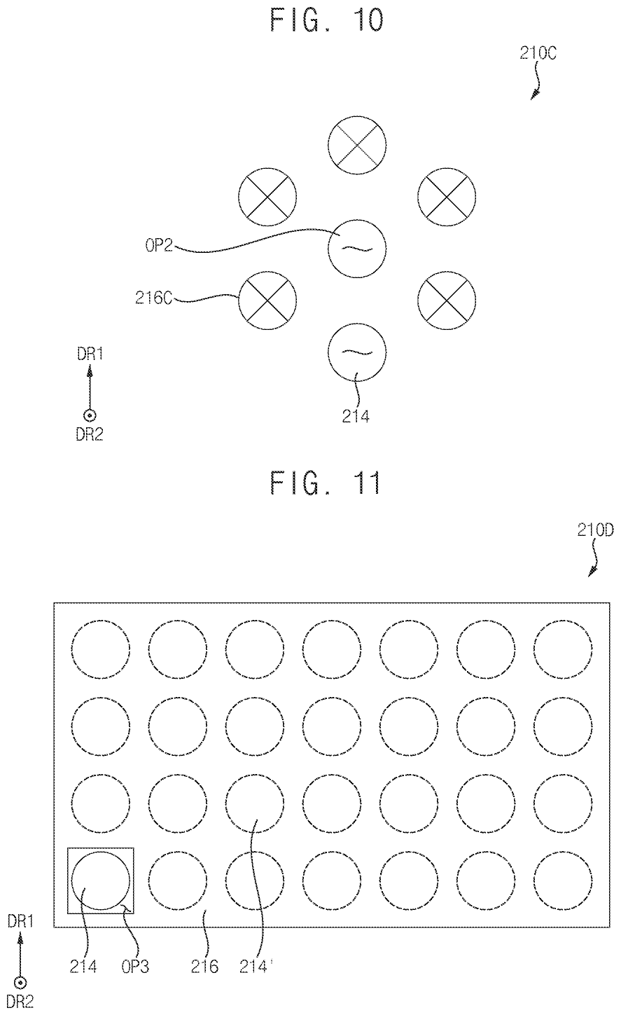

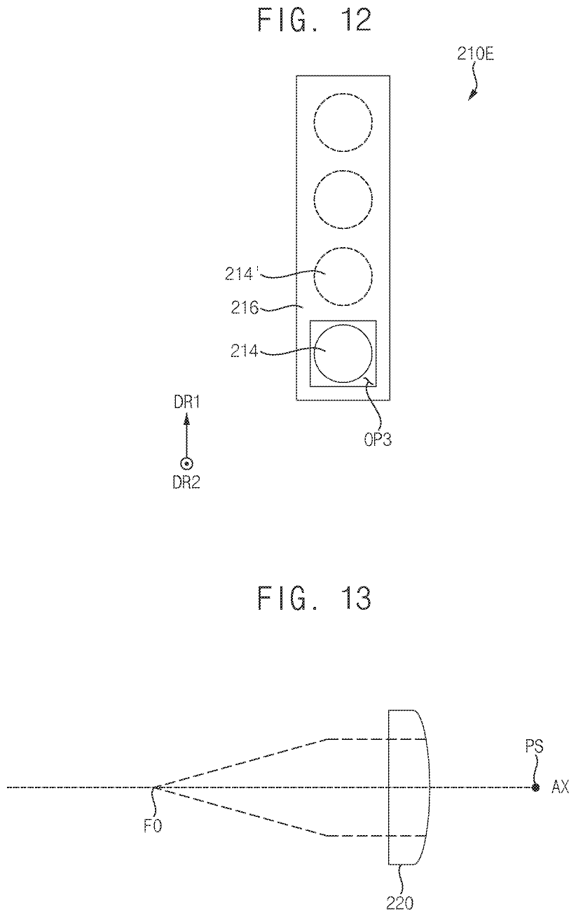

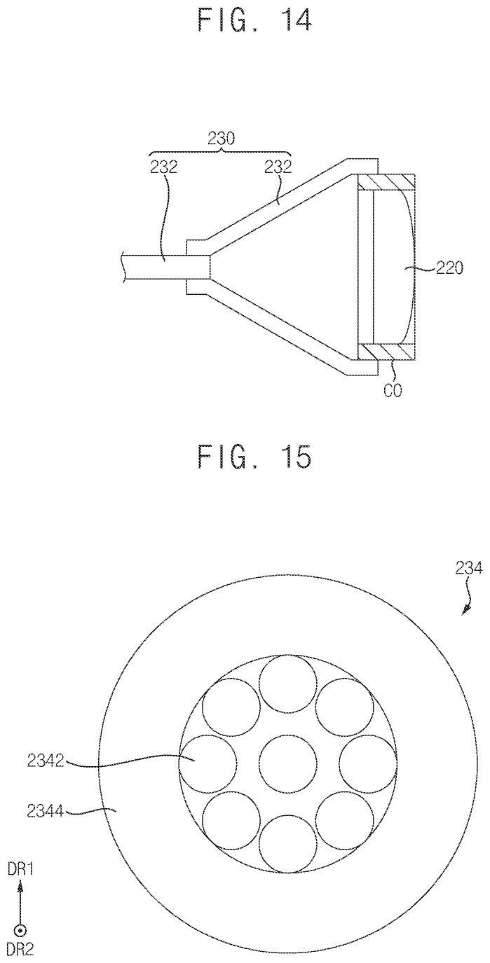

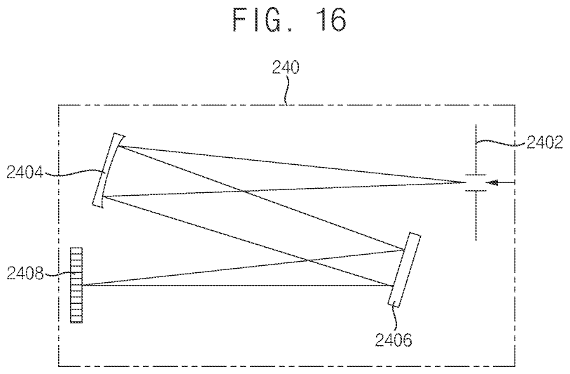

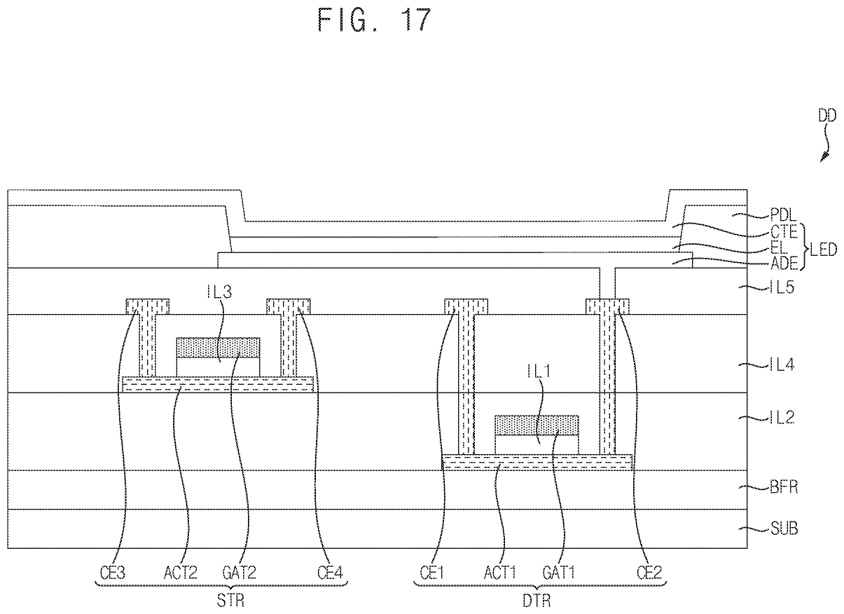

Particularly, FIG. 5 is a view illustrating detailed components of the data collector 20 included in the plasma monitoring system 1 of FIG. 1. FIGS. 6, 7, and 8 are views illustrating an embodiment of a view port structure 210A included in the data collector 20 of FIG. 5. FIG. 9 is a view illustrating an alternative embodiment of a view port structure 210B included in the data collector 20 of FIG. 5. FIG. 10 is a view illustrating another alternative embodiment of a view port structure 210C included in the data collector 20 of FIG. 5. FIG. 11 is a view illustrating another alternative embodiment of a view port structure 210D included in the data collector 20 of FIG. 5. FIG. 12 a view illustrating another alternative embodiment of a view port structure 210E included in the data collector 20 of FIG. 5. FIG. 13 is a view illustrating an embodiment of an optical lens 220 included in the data collector 20 of FIG. 5. FIGS. 14 and 15 are views illustrating an embodiment of an optical fiber 230 included in the data collector 20 of FIG. 5. FIG. 16 is a view illustrating an embodiment of the optical emission spectroscopy 240 included in the data collector of FIG. 5.

Referring to FIG. 5, an embodiment of the data collector 20 may include the viewport structure 210, the optical lens 220, the optical fiber 230, and the optical emission spectroscopy 240. In such an embodiment, as shown in FIG. 5, the data collector 20 may be disposed in the outer region SE2 of the chamber 110.

In an embodiment, the viewport structure 210 may be disposed the outside of the chamber 110. Although omitted for convenience of description in FIG. 5, the component for maintaining the vacuum may be further included between the viewport structure 210 and the chamber 110. The viewport structure 210 may allow light emitted from a plasma source PS located in the inner space SE1 of the chamber 110 to pass therethrough.

In an embodiment, the optical lens 220 may be disposed adjacent to the viewport structure 210. The component for maintaining the vacuum may be further included between the viewport structure 210 and the optical lens 220. The optical lens 220 may measure light emitted from the plasma source PS located at a certain distance or more from the viewport structure 210.

The optical fiber 230 may transfer the plasma light emitted from the plasma source PS to the optical emission spectroscopy 240. However, the disclosure is not limited thereto. In an alternative embodiment, for example, the data collector 20 may include other components capable of transferring the plasma light emitted from the plasma source PS to the optical emission spectroscopy 240.

In an embodiment, the optical emission spectroscopy 240 may be disposed in the outer region SE2 of the chamber 110. The optical emission spectroscopy 240 may receive the plasma light emitted from the plasma source PS and passed through the viewport structure 210. The optical emission spectroscopy 240 may analyze chemical species included in the plasma (e.g., the plasma PL of FIG. 2) through spectrum analysis.

Referring to FIGS. 1, 5, 6, 7, and 8, the viewport structure 210A according to an embodiment may include a view port VS and the shutter 216. In such an embodiment, the viewport structure 210A may correspond to the viewport structure 210 of FIG. 5. In an embodiment, as shown in FIG. 6, the viewport structure 210A may be connected to each of a driving device 250 and a cooling device 260. However, the disclosure is not limited thereto. Alternatively, the shutter 216 may be omitted.

In an embodiment, the viewport VS may include a frame 212, the plurality of light transmitting parts 214 and 214′, and a cold trap part OP2.

The plurality of light transmitting parts 214 and 214′ and the cold trap part OP2 may be defined or formed in the frame 212. Each of the plurality of light transmitting parts 214 and 214′ and the cold trap part OP2 may be spaced apart from each other. The frame 212 may include a metal material or the like.

In an embodiment, at least one of the plurality of light transmitting parts 214 and 214′ may pass the plasma light emitted from the plasma source PS. Each of the plurality of light transmitting parts 214 and 214′ may include a light transmitting material. In an embodiment, for example, the light transmitting material may be a glass, a quartz, or the like.

In an embodiment, one light transmitting part 214 among the plurality of light transmitting parts 214 and 214′ may be used for the plasma monitoring. When the plasma particles are deposited on the one light transmitting part 214 during the plasma monitoring process, the light transmittance of the one light transmitting part 214 may decrease. In this case, the plasma monitoring may be continued by replacing the one light transmitting part 214 with another light transmitting part 214′.

In an embodiment of the viewport structure 210A, as shown in FIGS. 6, 7, and 8, the plurality of light transmitting parts 214 and 214′ may be arranged in a circular array form. However, the disclosure is not limited thereto. In alternative embodiments, for example, the plurality of light transmitting parts 214 and 214′ may be arranged in other various forms.

FIGS. 6, 7, and 8 show an embodiment where six light transmitting parts 214 and 214′ having a circular shape are defined, however, the disclosure is not limited thereto. The number of the plurality of light transmitting parts 214 and 214′, the planar shape thereof, or the like may be variously modified. In an embodiment, for example, two or more of the plurality of light transmitting parts 214 and 214′ may be provided, and each of the plurality of light transmitting parts 214 and 214′ may have another one of various planar shapes such as a rectangle, an ellipse, or the like.

The cold trap part OP2 may aggregate and collect the plasma particles. In an embodiment, for example, the cold trap part OP2 may be provided as (or defined by) a cylindrical opening. The aggregated plasma particles may be deposited in an inner space of the cold trap OP2.

Although FIG. 6 shows an embodiment where the cold trap part OP2 is located at a center of the viewport structure 210A, however, the disclosure is not limited thereto. In an embodiment, for example, the location of the cold trap part OP2 may be variously changed.

In an embodiment, as shown in FIG. 6, the cold trap part OP2 and the plurality of light transmitting parts 214 and 214′ are separately included in the viewport structure 210A, however, the disclosure is not limited thereto. In an alternative embodiment, for example, one of the plurality of light transmitting parts 214 and 214′ may be used as the cold trap part OP2.

In an embodiment, the shutter 216 may be disposed between the viewport VS and the chamber 110. A third opening OP3 may be defined in the shutter 216. The third opening OP3 may overlap at least one of the plurality of light transmitting parts 214 and 214′.

In an embodiment, the plasma monitoring system 1 according to embodiments of the disclosure may further include the driving device 250. In an embodiment, the driving device 250 may be connected to the viewport VS. The driving device 250 may move the viewport VS.

In an embodiment, the driving device 250 may linearly move the viewport VS. The driving device 250 may move the viewport VS up, down, left, and right. In such an embodiment, the driving device 250 may overlap the first opening OPI defined by the gate valve 180 with another light transmitting part 214′. Accordingly, the plasma light emitted from the plasma source PS may be continuously transmitted to the optical emission spectroscopy 240 through the other light transmitting part 214′.

In an embodiment, the driving device 250 may rotate and move the viewport VS. The driving device 250 may rotate the viewport VS. In such an embodiment, the driving device 250 may overlap the first opening OPI defined by the other light transmitting unit 214′, the gate valve 180, and the third opening OP3 defined by the shutter 216. Accordingly, the plasma light emitted from the plasma source PS may be continuously transmitted to the optical emission spectroscopy 240 through the other light transmitting part 214′.

In an embodiment, the plasma monitoring system 1 may further include the cooling device 260. The cooling device 260 may be connected to the cold trap part OP2. In an embodiment, for example, the cooling device 260 may be provided in various ways such as a water cooling type, an air cooling type capable of condensing the plasma particles, or the like.

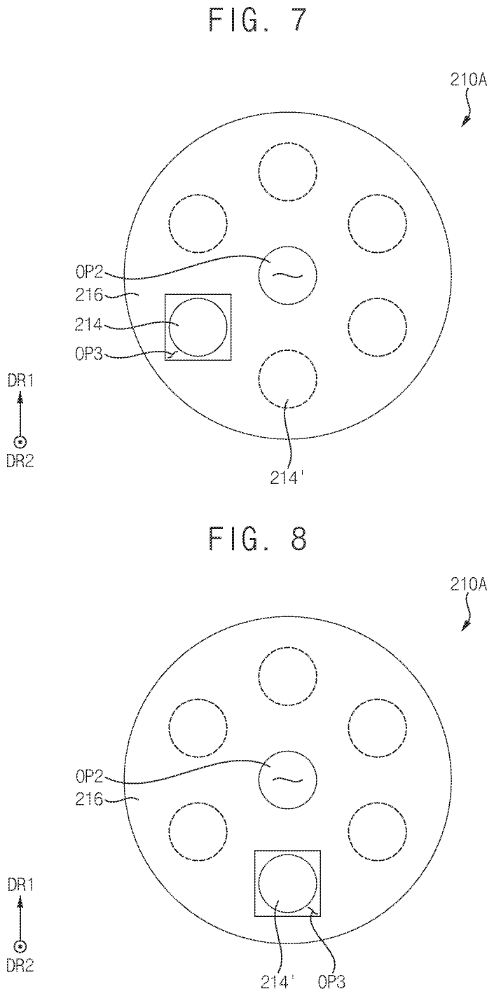

As shown in FIG. 7, when the third opening OP3 overlaps the one light transmitting part 214, the plasma monitoring may be performed through the one light transmitting part 214. In this case, the other light transmitting part 214′ may be shielded by the shutter 216. Accordingly, the shutter 216 may effectively prevent the plasma particles from being deposited on the other light transmitting part 214′.

When the plasma monitoring is performed through the one light transmitting part 214, the plasma particles may be deposited on the one light transmitting part 214. As the thickness at which the plasma particles are deposited increases, the light transmittance of the one light transmitting part 214 may decrease. In this case, as shown in FIG. 8, the plasma monitoring may be continued through the other light transmitting part 214′.

Referring to FIGS. 1, 5, and 9, an embodiment of the viewport structure 210B may include the viewport VS and a shutter 216B. In such an embodiment, the viewport structure 210B may correspond to the viewport structure 210 of FIG. 5.

The viewport structure 210B according to the embodiment of FIG. 9 may be substantially the same as or similar to the viewport structure 210A according to the embodiment of FIG. 6. However, the viewport structure 210B according to the embodiment of FIG. 9 may differ from the viewport structure 210A according to the embodiment of FIG. 6 in a location where the viewport structure 210A and the driving device 250 are connected. In an embodiment of the viewport structure 210B, as shown in FIG. 9, a driving device 270 may be connected to the shutter 216B, while in the viewport structure 210A according to the embodiment of FIG. 6, the driving device 250 may be connected to the viewport VS. Therefore, hereinafter, the shutter 216B and the driving device 270 will be mainly described.

In an embodiment of the viewport structure 210B, as shown in FIG. 9, may include the viewport VS and the shutter 216B. The view port VS may include the frame 212, the plurality of light transmitting parts 214 and 214′, and the cold trap part OP2.

In an embodiment, the shutter 216B may be disposed between the viewport VS and the chamber 110. The third opening OP3 may be defined in the shutter 216B. The third opening OP3 may overlap at least one of the plurality of light transmitting parts 214 and 214′.

In an embodiment, the driving device 270 may be coupled to shutter 216B. The driving device 270 may move the shutter 216B. In an embodiment, the driving device 270 may linearly move the shutter 216B. In an alternative embodiment, the driving device 270 may rotate and move the shutter 216B.

As described above with reference to FIGS. 7 and 8, the one light transmitting part 214 overlapping the third opening OP3 defined in the shutter 216B may transmit the light. The shutter 216B may shield the other light transmitting parts except for the one light transmitting part 214 to prevent the plasma particles from being deposited on the remaining light transmitting parts.

A diameter of the first opening OP1 defined by the gate valve 180 may be a same as a diameter of the shutter 216B. In this case, as only the shutter 216B rotates, a process of aligning of at least one of the first opening OP1 defined by the gate valve 180, the plurality of light transmitting parts 214 and 214′ defined in the viewport VS, and the third opening OP3 defined by the shutter 216B may be omitted. Specifically, a center of the first opening OP1 defined by the gate valve 180, the center of the view port VS, and a center of the third opening OP3 defined by the shutter 216B may be first aligned, and then, the sputtering process may be performed while rotating only the shutter 216B. As the process of aligning is omitted, a sputtering process time may be shortened.

Referring to FIGS. 1, 5, and 10, an alternative embodiment of the viewport structure 210C may include the viewport VS and a plurality of shutters 216C. In such an embodiment, the viewport structure 210C may correspond to the viewport structure 210 of FIG. 5.

Hereinafter, any repetitive detailed descriptions of the same or like elements as those of the viewport structure 210A or 210B described above with reference to FIGS. 1 to 9 will be omitted or simplified.

In such an embodiment, as shown in FIGS. 1, 5, and 10, the viewport structure 210C may include the viewport VS and the plurality of shutters 216C. The viewport VS may include the frame 212, the plurality of light transmitting parts 214 and 214′, and the cold trap part OP2.

In an embodiment, the plurality of shutters 216C may be disposed between the viewport VS and the chamber 110. The third opening OP3 may be defined in each of the plurality of shutters 216C. The third opening OP3 defined in each of the plurality of shutters 216C may overlap the plurality of light transmitting parts 214 and 214′, respectively.

Each of the plurality of shutters 216C may be opened/closed in conjunction with the plasma monitoring operation. In an embodiment, for example, at least one of the plurality of shutters 216C may be opened to transmit the plasma light emitted from the plasma source PS to the one light transmitting part 214. In such an embodiment, remaining of the plurality of shutters 216C that do not overlap the one light transmitting part 214 may be closed to prevent the deposition of the plasma particles.

Referring to FIGS. 5, 11, and 12, alternative embodiments of the viewport structure 210D or 210E correspond to the viewport structure 210 of FIG. 5, respectively. Hereinafter, any repetitive detailed descriptions of the same or like elements as those of the viewport structures 210A, 210B, and 210C described above with reference to FIGS. 1 to 10 will be omitted or simplified.

In an embodiment, as shown in FIGS. 5, 11, and 12, the viewport structure 210D or 210E may be of a plate type. The plate type may include the plurality of light transmitting parts 214 and 214′ in greater number than a revolver type viewport structures 210A, 210B, and 210C described above. Accordingly, such an embodiment of the viewport structure 210D or 210E may have a longer use cycle than the view port structures 210A, 210B, and 210C described above.

As shown in FIG. 11, in an embodiment of the viewport structure 210D, the plurality of light transmitting parts 214 and 214′ may be arranged in an nxm (n by m) matrix from. However, n may be a natural number of 1 or greater, and m may be the natural number of 2 or greater.

As shown in FIG. 12, in an alternative of the viewport structure 210E, the plurality of light transmitting parts 214 and 214′ may be arranged in a row. In an embodiment, for example, the plurality of light transmitting parts 214 and 214′ may be arranged in the first direction DR1. However, the disclosure is not limited thereto. In an alternative embodiment, for example, the plurality of light transmitting parts 214 and 214′ may be arranged in a direction crossing the first direction DR1.

As described above with reference to FIGS. 1, 6 to 8, 9, 10, 11, and 12, embodiments of the plasma monitoring system 1 may have the viewport structure (e.g., the viewport structure 210A shown in FIGS. 6, 7, and 8, the viewport structure 210B shown in FIG. 9, the viewport structure 210C shown in FIG. 10, the viewport structure 210D shown in FIG. 11, and the viewport structure 210E shown in FIG. 12). The view port structure may be disposed outside the chamber 110.

The viewport structure may include the plurality of light transmitting parts 214 and 214′. Among the plurality of light transmitting parts 214 and 214′, the one light transmitting part 214 may be used for the plasma monitoring. When the plasma particles are deposited on the one light transmitting part 214 during the plasma monitoring process, the light transmittance of the one light transmitting part 214 may decrease. In this case, the plasma monitoring may be continued by replacing with the other light transmitting part 214′.

In such an embodiment, the viewport structure may include the shutters (e.g., the shutter 216 of FIGS. 6, 7, 8, 11, and 12, the shutter 216B of FIG. 9, and the plurality of shutters 216C of FIG. 10). The shutter may shield the other light transmitting parts other than at least one light transmitting part used for the plasma monitoring among the plurality of light transmitting parts 214 and 214′. The shutter may prevent the plasma particles from being deposited on the remaining light transmitting parts. Accordingly, the plasma monitoring may be continued while the sputtering process is in progress.

Referring to FIGS. 1, 5, and 13, the plasma monitoring system 1 according to embodiments of the disclosure may include the optical lens 220. In an embodiment, the optical lens 220 may be disposed between the viewport structure 210 and the optical emission spectroscopy 240. In an embodiment, for example, the plasma source PS may be positioned on an optical axis AX of the optical lens 220, and a focal point of the optical lens 220 may be positioned on an incident surface of the optical fiber 230. However, the disclosure is not limited thereto. In an embodiment, for example, the position of the optical lens 220 may be variously changed.

In an embodiment, the optical lens 220 may be a convex lens. Accordingly, the optical lens 220 may measure the plasma light emitted from the plasma source PS located at the certain distance or more. In an embodiment, for example, the plasma monitoring system 1 according to embodiments of the disclosure may measure the plasma source PS located at the center of the chamber 110 through the convex lens. Accordingly, detection of the abnormal state of the plasma, spatial analysis of the plasma state, or the like may be performed more precisely.

However, the disclosure is not limited thereto. In an embodiment, for example, the optical lens 220 may further include one or more lenses. In an embodiment, for example, the optical lens 220 may further include the concave lens. In an alternative embodiment, for another example, the optical lens 220 may be omitted.

FIGS. 5 and 13 show only the one plasma source PS, however, the disclosure is not limited thereto. In an embodiment, for example, a plurality of plasma light sources may exist in the inner space (i.e., the inner region SE1) of the chamber 110. The illustrated plasma source PS may be any one of the plurality of plasma light sources.

Referring to FIGS. 5, 14, and 15, the plasma monitoring system 1 according to embodiments of the disclosure may further include the optical fiber 230.

The plasma light emitted from the plasma source PS may pass through the viewport structure 210. The plasma light passed through the viewport structure 210 may pass through the optical lens 220. The plasma light passed through the optical lens 220 may be transmitted to the optical emission spectroscopy 240 through the optical fiber 230. Each of the viewport structure 210 and the optical lens 220 may be disposed within a cover structure CO. Accordingly, a vacuum state may be maintained.

In an embodiment, for example, the optical fiber 230 may include an optical fiber coupler 232 and optical cables 234.

The optical fiber coupler 232 may couple the optical fiber 230 to another device. In an embodiment, for example, the optical fiber coupler 232 may couple the optical cable 234 to the cover structure CO. FIG. 14 shows an embodiment where an area of an incident surface of the optical fiber coupler 232 is greater than an area of an exit surface of the optical fiber coupler 232, however, the disclosure is not limited thereto. In an embodiment, for example, the optical fiber coupler 232 may have various shapes and structures. Alternatively, the optical fiber coupler 232 may be omitted.

As shown in FIG. 15, an embodiment of the optical cable 234 may include a core 2342 and a coating layer 2344. The core 2342 may include one or more optical fibers. The optical fiber may totally reflect an incident light and transmit the incident light to the optical emission spectroscopy 240. The optical fiber may include various materials such as silicon, fluorine, plastic, rare earth, or the like. The coating layer 2344 may protect the core 2342.

However, the disclosure is not limited thereto. In an embodiment, for example, the optical cable 234 may be disposed in each of the plurality of light transmitting parts 214 and 214′. In such an embodiment, the process of aligning the plurality of light transmitting parts 214 and 214′ and the optical cable 234 may be omitted. Accordingly, an align process time may be saved. Alternatively, the optical cable 234 may be disposed only in one of the plurality of light transmitting parts 214 and 214′. In such an embodiment, equipment installation cost may be saved.

Referring to FIGS. 1, 5 and 16, the plasma monitoring system 1 according to embodiments of the disclosure may include the optical emission spectroscopy 240.

The optical emission spectroscopy 240 may be disposed outside the chamber 110, and may receive the plasma light transmitted through at least one of the plurality of light transmitting parts 214 and 214′ included in the viewport structure 210 to monitor the plasma.

In an embodiment, for example, the optical emission spectroscopy 240 may include an incident part 2402, at least one mirror 2404, a diffracting part 2406, and a detector 2408.

The plasma light transmitted through at least one of the plurality of light transmitting parts 214 and 214′ may be incident to the incident part 2402. In an embodiment, for example, at least one opening may be defined in the incident part 2402. Accordingly, the plasma light may pass therethrough.

The plasma light passed through the incident part 2402 may diverge. The plasma light may be incident on the mirror 2404. In an embodiment, for example, the mirror 2404 may be an imaging mirror, a collimating mirror, or the like. The imaging mirror may converge the plasma light. The collimating mirror may convert the plasma light into parallel light.

Light reflected by the mirror 2404 may be incident on the diffracting part 2406. In an embodiment, for example, the diffracting part 2406 may include a planar diffraction grating. The light incident on the planar diffraction grating may be spectrally resolved.

The light emitted from the diffracting part 2406 may be incident to the detector 2408. In an embodiment, for example, the detector 2408 may be a charged coupled device (CCD). The light incident on the detector 2408 may generate data (e.g., the emission spectrometry analysis data S2 of FIG. 1) used for monitoring the plasma. the plasma data S1 may be transmitted to the controller 30. Accordingly, the sputtering process may be monitored and controlled in real-time.

The controller 30 may be composed of a general personal computer (PC), a workstation, a supercomputer, or the like. An analysis program for analyzing the plasma state may be installed in the controller 30. The controller 30 may analyze the inside of the chamber 110, in particular, the plasma state at a local location within the chamber 110, using the analysis program based on the data on the plasma light received from the optical emission spectroscopy (e.g., the optical emission spectroscopy 240 of FIG. 5).

In an embodiment, after analyzing the plasma state of the local location through the analysis program, if the plasma state is out of an allowable (or a predetermined) range, the controller 30 may analyze causes and suggest new process conditions for the corresponding plasma process. In an embodiment, for example, the plasma process may be etching, deposition (e.g., including the sputtering process), diffusion, surface treatment, new material synthesis process, or the like.

The plasma monitoring system 1 according to embodiments of the disclosure may optimize the plasma process by monitoring and controlling the plasma state. In such embodiments, as the thin film is formed based on an optimized plasma process, a device (e.g., thin film transistor) may be implemented with high reliability.

FIG. 17 is a cross-sectional view illustrating a display device that is an example of an object that may be formed using the plasma monitoring system of FIG. 1.

The plasma monitoring system 1 of FIG. 1 may form various thin films through the sputtering process. In an embodiment, for example, the thin film may be a first active pattern ACTI and a second active pattern ACT2 included in a display device DD.

The display device DD may include a base substrate BSUB, a buffer layer BFR, a driving transistor DTR, a switching transistor STR, a plurality of insulating layers IL1, IL2, IL3, IL4, and IL5, a pixel defining layer PDL, and a light emitting device LED. The driving transistor DTR may include a first active pattern ACTI, a first gate electrode GAT1, a first connection electrode CE1, and a second connection electrode CE2. The switching transistor STR may include a second active pattern ACT2, a second gate electrode GAT2, a third connection electrode CE3 and a fourth connection electrode CE4.

The base substrate SUB may include a transparent material or an opaque material. In an embodiment, examples of materials that may be used as the base substrate SUB may include glass, quartz, plastic, or the like. These may be used alone or in combination with each other.

The buffer layer BFR may be disposed on the base substrate SUB. In an embodiment, the buffer layer BFR may include or be formed of an inorganic insulating material. The buffer layer BFR may prevent metal atoms or impurities from diffusing into the first active pattern ACTI from the base substrate SUB.

The first active pattern ACTI may be disposed on the buffer layer BFR. In an embodiment, the first active pattern ACTI may be formed by depositing an oxide thin film on the buffer layer BFR using the plasma monitoring system 1 of FIG. 1. Accordingly, the first active pattern ACTI may include an oxide semiconductor. In such an embodiment, the oxide semiconductor included in the first active pattern ACTI may correspond to the metal oxide included in the target (e.g. the target TA of FIG. 2).

Examples of the oxide semiconductor that may be used as the first active pattern ACTI may include zinc oxide (ZnOx), gallium oxide (GaOx), tin oxide (SnOx), titanium oxide (TiOx), indium oxide (InOx), indium-Gallium Oxide (IGO), Indium-Zinc Oxide (IZO), Gallium-Zinc Oxide (GZO), Zinc-Tin Oxide (ZTO), Zinc-Magnesium Oxide (ZMO), Zinc-Zirconium Oxide (ZnZrxOy), Indium-Zinc-Tin oxide (IZTO), indium-gallium-zinc oxide (IGZO), indium-gallium-hafnium oxide (IGHO), tin-aluminum-zinc oxide (TAZO), indium-gallium-tin oxide (IGTO) and indium-tin-gallium-zinc oxide (ITGZO), or the like. These may be used alone or in combination with each other.

FIG. 17 shows an embodiment where the first active pattern ACTI includes the oxide semiconductor. In an alternative embodiment, the first active pattern ACTI may include a silicon semiconductor.

The first insulating layer ILI may be disposed on the first active pattern ACT1. The first insulating layer ILI may insulate the first active pattern ACTI from the first gate electrode GAT1. In an embodiment, the first insulating layer IL1 may include an inorganic insulating material.

The first gate electrode GATI may be disposed on the first insulating layer IL1. The first gate electrode GATI may overlap the first active pattern ACT1. In an embodiment, the first gate electrode GATI may include a metal, an alloy, a conductive metal oxide, a transparent conductive material, or the like.

The second insulating layer IL2 may be disposed on the buffer layer BFR to cover the first active pattern ACTI and the first gate electrode GAT1. In an embodiment, the second insulating layer IL2 may include an inorganic insulating material.

The second active pattern ACT2 may be disposed on the second insulating layer IL2. In an embodiment, the second active pattern ACT2 may be formed by depositing an oxide thin film on the second insulating layer IL2 using the plasma monitoring system 1 of FIG. 1. Accordingly, the second active pattern ACT2 may include an oxide semiconductor. In such an embodiment, the oxide semiconductor included in the second active pattern ACT2 may correspond to the metal oxide included in the target.

Examples of the oxide semiconductor that may be used as the second active pattern ACT2 may include zinc oxide (ZnOx), gallium oxide (GaOx), tin oxide (SnOx), titanium oxide (TiOx), indium oxide (InOx), indium-Gallium Oxide (IGO), Indium-Zinc Oxide (IZO), Gallium-Zinc Oxide (GZO), Zinc-Tin Oxide (ZTO), Zinc-Magnesium Oxide (ZMO), Zinc-Zirconium Oxide (ZnZrxOy), Indium-Zinc-Tin oxide (IZTO), indium-gallium-zinc oxide (IGZO), indium-gallium-hafnium oxide (IGHO), tin-aluminum-zinc oxide (TAZO), indium-gallium-tin oxide (IGTO), indium-tin-gallium-zinc oxide (ITGZO), or the like. These may be used alone or in combination with each other.

The third insulating layer IL3 may be disposed on the second active pattern ACT2. The third insulating layer IL3 may insulate the second active pattern ACT2 from the second gate electrode GAT2. In an embodiment, the third insulating layer IL3 may include an inorganic insulating material.

The second gate electrode GAT2 may be disposed on the third insulating layer IL3. The second gate electrode GAT2 may overlap the second active pattern ACT2. In an embodiment, the second gate electrode GAT2 may include a metal, an alloy, a conductive metal oxide, a transparent conductive material, or the like.

The fourth insulating layer IL4 may be disposed on the second insulating layer IL2 to cover the second active pattern ACT2 and the second gate electrode GAT2. In an embodiment, the fourth insulating layer IL4 may include an inorganic insulating material.

The first to fourth connection electrodes CE1, CE2, CE3, and CE4 may be disposed on the fourth insulating layer IL4. Each of the first connection electrode CEI and the second connection electrode CE2 may contact the first active pattern ACTI through contact holes. Each of the third connection electrode CE3 and the fourth connection electrode CE4 may contact the second active pattern ACT2 through contact holes.

As described above, the first active pattern ACT1, the first gate electrode GAT1, the first connection electrode CE1, and the second connection electrode CE2 may constitute the driving transistor DTR. The second active pattern ACT2, the second gate electrode GAT2, the third connection electrode CE3, and the fourth connection electrode CE4 may constitute the switching transistor STR.

In an embodiment, where both the first active pattern ACTI and the second active pattern ACT2 include an oxide semiconductor, both the driving transistor DTR and the switching transistor STR may be oxide transistors. In an embodiment, where the first active pattern ACTI includes a silicon semiconductor, the driving transistor DTR may be a silicon transistor in.

The fifth insulating layer IL5 may be disposed on the fourth insulating layer IL4 to cover the first to fourth connection electrodes CE1, CE2, CE3, and CE4. In an embodiment, the fifth insulating layer IL5 may include an organic insulating material.

The light emitting device LED and the pixel defining layer PDL may be disposed on the fifth insulating layer IL5. The light emitting device LED may include an anode electrode ADE, a light emitting layer EL, and a cathode electrode CTE.

The anode electrode ADE may be disposed on the fifth insulating layer IL5. The anode electrode ADE may be electrically connected to the driving transistor DTR through a contact hole defined or formed in the fifth insulating layer IL5.

The anode electrode ADE may include a metal, an alloy, a metal oxide, a transparent conductive material, or the like. Examples of materials that may be used as the anode electrode (ADE) may include silver (Ag), an alloy containing silver, molybdenum (Mo), an alloy containing molybdenum, aluminum (Al), an alloy containing aluminum, Aluminum nitride (AIN), tungsten (W), tungsten nitride (WN), copper (Cu), nickel (Ni), chromium (Cr), chromium nitride (CrN), titanium (Ti), tantalum (Ta), platinum (Pt), scandium (Sc), indium-tin oxide (ITO), indium-zinc oxide (IZO), or the like. These may be used alone or in combination with each other.

In an embodiment, when the anode electrode ADE includes a metal oxide, the anode electrode ADE may be formed by depositing an oxide thin film using the plasma monitoring system 1. In such an embodiment, the metal oxide included in the anode electrode ADE may correspond to the metal oxide included in the target TA.

The pixel defining layer PDL may be disposed on the fifth insulating layer IL5. A pixel opening extending to and exposing a portion of the anode electrode ADE may be defined in the pixel defining layer PDL. In an embodiment, the pixel defining layer PDL may include an organic material.

The light emitting layer EL may be disposed on the anode electrode ADE. In an embodiment, the light emitting layer EL may be disposed on the portion of the anode electrode ADE exposed by the pixel opening. In an alternative embodiment, the light emitting layer EL may be disposed on the anode electrode ADE and the pixel defining layer PDL.

The cathode electrode CTE may be disposed on the light emitting layer EL. The light emitting layer EL may emit light based on a voltage difference between the anode electrode ADE and the cathode electrode CTE.

A structure of the display device DD shown in FIG. 17 is only an example, and may be variously changed. In an embodiment, for example, any one of several components included in the display device DD may be omitted, or components not shown in FIG. 17 may be further included. In embodiments, a connection structure of various elements included in the display device DD may be variously changed.

In an embodiment, the display device DD may be an organic light emitting display device (OLED). In an alternative embodiment, the display device (DD may be a liquid crystal display device (LCD), a field emission display device (FED), a plasma display device (PDP), an electrophoretic display device (EPD), a quantum dot display device, an inorganic light emitting display device, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A plasma monitoring system comprising:
a gate valve disposed on a first side of a chamber, wherein the gate valve is opened or closed in conjunction with a plasma monitoring operation;
a viewport structure disposed outside the chamber and including a plurality of light transmitting parts; and
an optical emission spectroscopy disposed outside the chamber, wherein the optical emission spectroscopy monitors plasma by receiving plasma light transmitted through at least one of the plurality of light transmitting parts of the viewport structure.

2. The plasma monitoring system of claim 1, wherein the gate valve is opened only during the plasma monitoring operation.

3. The plasma monitoring system of claim 1, wherein,
the viewport structure further includes a driving device connected to the viewport structure, and
the driving device rotates or linearly moves the viewport structure.

4. The plasma monitoring system of claim 1, wherein,
the viewport structure further includes a cold trap part spaced apart from the plurality of light transmitting parts, and
the cold trap part aggregates and collects plasma particles.

5. The plasma monitoring system of claim 1, further comprising:
a shutter disposed between the viewport structure and the chamber.

6. The plasma monitoring system of claim 5, wherein,
a third opening is defined in the shutter, and
the third opening overlaps at least one of the plurality of light transmitting parts.

7. The plasma monitoring system of claim 1, further comprising:
an optical lens disposed between the viewport structure and the optical emission spectroscopy.

8. The plasma monitoring system of claim 7, wherein the optical lens is a convex lens.

9. The plasma monitoring system of claim 1, wherein the plurality of light transmitting parts are arranged in a circular array form in the viewport structure.

10. The plasma monitoring system of claim 1, wherein the plurality of light transmitting parts are arranged in an n×m matrix form in the viewport structure, wherein n is a natural number of 1 or greater, and m is the natural number of 2 or greater.

11. A plasma monitoring system comprising:
a gate valve disposed on a first side of a chamber, wherein the gate valve is opened or closed in conjunction with a plasma monitoring operation;
a viewport structure disposed outside the chamber and including a plurality of light transmitting parts;
a shutter disposed between the viewport structure and the chamber, wherein the shutter rotates or linearly moves; and
an optical emission spectroscopy disposed outside the chamber, wherein the optical emission spectroscopy monitors plasma by receiving plasma light transmitted through at least one of the plurality of light transmitting parts of the viewport structure.

12. The plasma monitoring system of claim 11, wherein the gate valve is opened only during the plasma monitoring operation.

13. The plasma monitoring system of claim 11, wherein,
the viewport structure further includes a cold trap part spaced apart from plurality of light transmitting parts, and
the cold trap part aggregates and collects plasma particles.

14. The plasma monitoring system of claim 11, wherein,
a third opening is defined in the shutter, and
the third opening overlaps at least one of the plurality of light transmitting parts.

15. The plasma monitoring system of claim 14, wherein the shutter is provided in plurality to overlap the plurality of light transmitting parts, respectively.

16. The plasma monitoring system of claim 14, wherein,
the shutter further includes a driving device which rotates or linearly moves the viewport structure.

17. The plasma monitoring system of claim 11, further comprising:
an optical lens disposed between the viewport structure and the optical emission spectroscopy.

18. The plasma monitoring system of claim 17, wherein the optical lens is a convex lens.

19. The plasma monitoring system of claim 11, wherein the plurality of light transmitting parts are arranged in a circular array form in the viewport structure.

20. The plasma monitoring system of claim 11, wherein the plurality of light transmitting parts are arranged in an nxm matrix form in the viewport structure, wherein n is a natural number of 1 or greater, and m is the natural number of 2 or greater.
